(19) United States
(12) Patent Application Publication
(10) Pub. No.: US 2019/0341784 A1
(43) Pub. Date: Nov. 7, 2019

(54) BATTERY CHARGING SYSTEM AND BATTERY CHARGING METHOD

(71) Applicant: PEGATRON CORPORATION, Taipei City (TW)

(72) Inventors: Yi-Hsuan Lee, TAIPEI CITY (TW); Hsueh-Cheng Lu, TAIPEI CITY (TW); Shih-Feng Tseng, TAIPEI CITY (TW); Chun-Wei Ko, TAIPEI CITY (TW); Chih-Chiang Yu, TAIPEI CITY (TW)

(21) Appl. No.: 16/290,976

(22) Filed: Mar. 4, 2019

(30) Foreign Application Priority Data
May 3, 2018 (TW) 107114959

(51) Int. Cl. H02J 7/00; G01R 31/389; G01R 31/3842; H01M 10/44

(52) U.S. Cl. CPC H02J 7/007; H01M 10/44; G01R 31/3842; G01R 31/389

(57) ABSTRACT

A battery charging system is provided, and includes a control unit, a charging unit, and a measurement unit. The control unit is configured to generate and output a control signal. The charging unit is coupled to the control unit and a battery. The charging unit is configured to receive the control signal, generate a charging current according to the control signal, and output the charging current to charge the battery. The measurement unit is coupled to the battery and the control unit. The measurement unit is configured to measure a battery voltage output by the battery, and output a measurement signal to the control unit. The measurement signal corresponds to the battery voltage.

### CROSS REFERENCE TO RELATED APPLICATION

This application is based upon and claims priority of Taiwan Patent Application No. 107114959, filed on May 3, 2018, the contents being incorporated herein by reference.

### BACKGROUND OF THE INVENTION

### 1. Field of the Invention

The present application relates to a battery charging system, and in particular, to a battery charging system capable of adjusting a charging current according to an internal resistance value of a battery.

### 2. Description of the Prior Art

Rechargeable batteries are commonly used in portable devices. For example, in notebook computers, mobile phones, and tablet computers, applications thereof can be seen. Currently, some rechargeable batteries can already withstand a high charging current, to support fast charging.

For example, fast charging can be achieved if a relatively high charging current is applied to a battery, thereby improving convenience in use. However, if a relatively high charging current is applied to the battery, aging of the battery may be accelerated. If an aging degree of the battery already reaches a predetermined level, a relatively high charging current is still applied thereto, an overall service life of the battery will be shortened.

To avoid shortening of a service life of a battery, a relatively low charging current maybe applied to the battery to perform charging at a general speed. This can avoid excessively rapid aging of the battery and extend a battery life, but may lead to excessively slow charging and inconvenience a user.

### SUMMARY OF THE INVENTION

In view of the foregoing engineering problem that it is difficult to balance a charging speed and a battery aging speed, the following embodiments provide a solution.

According to an embodiment, a battery charging system is provided, and includes a control unit, a charging unit, and a measurement unit. The control unit is configured to generate and output a control signal. The charging unit is coupled to the control unit and a battery, where the charging unit is configured to receive the control signal, generate a charging current according to the control signal, and output the charging current to charge the battery. The measurement unit is coupled to the battery and the control unit, and configured to measure a battery voltage output by the battery, and output a measurement signal to the control unit, where the measurement signal corresponds to the battery voltage.

According to an embodiment, a battery charging method is provided, and is applied to a battery charging system. The battery charging system includes a control unit, a charging unit, and a measurement unit. The method includes: generating, by the control unit, a control signal; receiving, by the charging unit, the control signal, and outputting a charging current to a battery according to the control signal; outputting, by the battery, a battery voltage to the measurement unit; and outputting, by the measurement unit, a measurement signal to the control unit, where the measurement signal corresponds to the battery voltage.

According to the battery charging system and the battery charging method provided by the embodiments, an engineering effect of balancing a charging speed for a battery and avoidance of excessively rapid aging of the battery can be achieved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a battery charging system according to an embodiment.

FIG. 2 is a waveform graph of an operation of the battery charging system in FIG. 1.

FIG. 3 is a schematic diagram of a waveform change of a charging current in FIG. 1.

FIG. 4 is a flowchart of a battery charging method for the battery charging system in FIG. 1.

### DETAILED DESCRIPTION

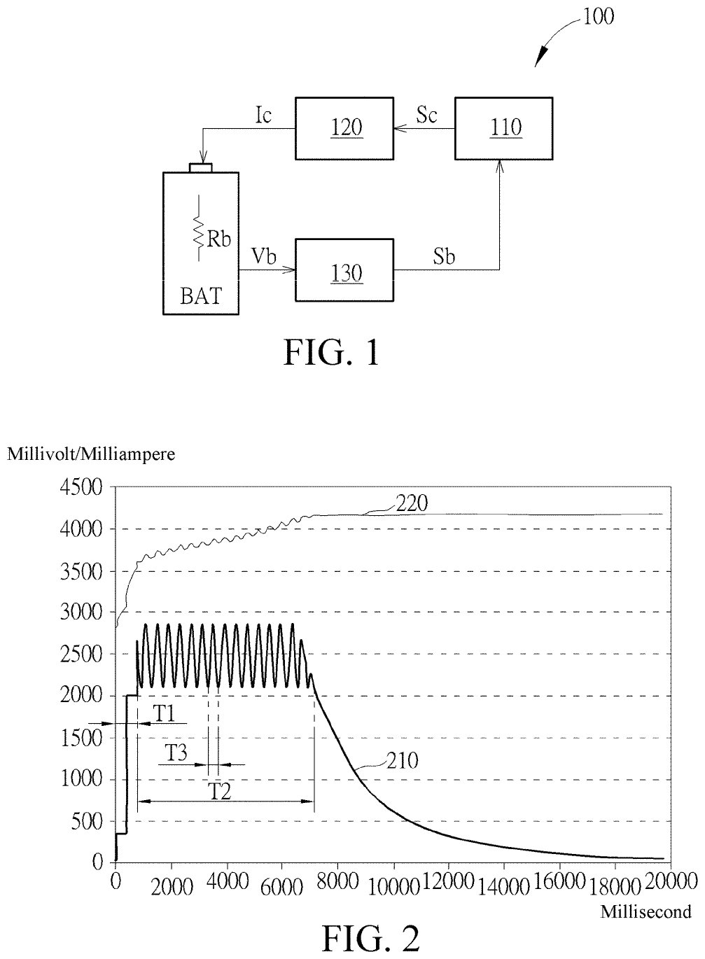

FIG. 1 is a schematic diagram of a battery charging system 100 according to an embodiment. The battery charging system 100 may include a control unit 110, a charging unit 120, and a measurement unit 130. The control unit 110 maybe configured to generate a control signal Sc, and the control signal Sc is output by a first end of the control unit 110. The charging unit 120 may be configured to generate a charging current Ic according to the control signal Sc. A first end of the charging unit 120 may be coupled to the first end of the control unit 110, to receive the control signal Sc. A second end of the charging unit 120 may be coupled to a first end of a battery BAT, to output the charging current Ic, so as to charge the battery BAT. A first end of the measurement unit 130 may be coupled to a second end of the battery BAT, to measure a battery voltage Vb output by the battery BAT, and a second end of the measurement unit 130 may be coupled to the second end of the control unit 110, to output a measurement signal Sb. The measurement signal Sb may correspond to the battery voltage Vb, and the control unit 110 may learn of the battery voltage Vb by receiving the measurement signal Sb.

According to this embodiment, the control unit 110 may obtain an internal resistance value Rb of the battery BAT according to the measurement signal Sb, and the control unit 110 may set the control signal Sc according to the obtained internal resistance value Rb. For example, if the control unit 110 learns through calculation that an internal resistance value Rb of the battery BAT does not reach a predetermined value, indicating that an aging degree of a cell of the battery BAT is not severe, the control unit 110 may set a control signal Sc to increase or not reduce the charging current Ic output by the charging unit 120. On the contrary, if the control unit 110 learns through calculation that an internal resistance value Rb of the battery BAT already reaches a predetermined value, indicating that an aging degree of a cell of the battery BAT already reaches a predetermined degree, the control unit 110 may set a control signal Sc to reduce or no increase the charging current Ic output by the charging unit 120. Another example is provided below for description.

As shown in FIG. 1, the control unit 110, the charging unit 120, the battery BAT, and the measurement unit 130 may form a closed-loop system. The control unit 110 may monitor the internal resistance value Rb of the battery BAT by using the measurement signal Sb continuously, and set and adjust the control signal Sc according to the internal resistance value Rb of the battery BAT, to determine the charging current Ic.

FIG. 2 is a waveform graph of an operation of the battery charging system in FIG. 1 according to an embodiment. In FIG. 2, a horizontal axis may be a time axis, and a unit may be, for example, millisecond (msec); and a vertical axis may correspond to voltage values and current values, and a unit may be, for example, milliampere (mA) and millivolt (mV). The charging current Ic may form a current waveform on the time axis according to the control signal Sc, as shown by a curved line 210. When the charging current Ic changes, the battery voltage Vb may form a voltage waveform on the time axis, as shown by a curved line 220. The control unit 110 may obtain the internal resistance value Rb of the battery BAT according to the current waveform and the voltage waveform, and set the control signal Sc according to the internal resistance value Rb.

In FIG. 2, a time period T1 may be a time period in which a start operation is performed. The control unit 110 controls, by using a control signal Sc, the charging unit 120 to pull up the charging current Ic to a predetermined value, for example (but is not limited to) , approximately 2000 mA. Ina time period T2, an internal resistance value Rb of the battery BAT may be measured. The control unit 110 controls, by using a control signal Sc, the charging unit 120 to enable current values of the charging current Ic to have an oscillation waveform on the time axis. In the time period T2, the current waveform of the charging current Ic may be, for example, a waveform that includes a sinusoidal wave, a triangular wave, a rectangular wave, or a repeated particular waveform.

A time period T3 may correspond to a predetermined cycle of the oscillation waveform of the charging current Ic, for example, a cycle of the curved line 210 from a valley to a valley, or a cycle of the curved line 210 from a peak to a peak. In the time period T3, the charging current Ic has a maximum current value Imax and a minimum current value Imin, and the battery voltage Vb has a maximum voltage value Vmax and a minimum voltage value Vmin. The internal resistance value Rb of the battery BAT may be obtained according to the maximum voltage value Vmax, the minimum voltage value Vmin, the maximum current value Imax, and the minimum current value Imin, and for example, may be represented as Rb=f(Imax,Imin,Vmax,Vmin), and f( ) herein may be a function expression.

According to another embodiment, the internal resistance value Rb may be directly proportional to a quotient of a difference between the maximum voltage value Vmax and the minimum voltage value Vmin and a difference between the maximum current value Imax and the minimum current value Imin. In other words, the internal resistance value Rb may be represented as Rb∝((Vmax−Vmin)/(Imax−Imin). For example, the internal resistance value Rb may be obtained by using the following mathematical equation: Rb=(Vmax−Vmin)/(Imax−Imin).

As described above, after calculating the internal resistance value Rb of the battery BAT, the control unit 110 may monitor whether the internal resistance value Rb is excessively high, to correspondingly set a control signal Sc. Table 1 is a table, in this embodiment, recorded after a battery voltage Vb and a charging current Ic are monitored in four cycles of a curved line 210, and an internal resistance value Rb is calculated in real time.

TABLE 1

| | | | Internal |
|---|---|---|---|
| | Battery voltage | | resistance |
| | Vb | Charging current Ic | value Rb |
| | (mV) | (mA) | (mΩ) |
| First cycle | 3702 (a maximum | 2862 (a maximum | |
| | voltage value | current value Imax) | |
| | Vmax) | | |
| | 3655 (a minimum | 2115 (a minimum | 63 |
| | voltage value | current value Imin) | |
| | Vmin) | | |
| Second | 3741 (a maximum | 2862 (a maximum | |
| cycle | voltage value | current value Imax) | |
| | Vmax) | | |
| | 3694 (a minimum | 2114 (a minimum | 63 |
| | voltage value | current value Imin) | |
| | Vmin) | | |
| Third cycle | 3833 (a maximum | 2862 (a maximum | |
| | voltage value | current value Imax) | |
| | Vmax) | | |
| | 3783 (a minimum | 2114 (a minimum | 67 |
| | voltage value | current value Imin) | |
| | Vmin) | | |
| Fourth | 3905 (a maximum | 2863 (a maximum | |
| cycle | voltage value | current value Imax) | |
| | Vmax) | | |
| | 3856 (a minimum | 2114 (a minimum | 65 |
| | voltage value | current value Imin) | |
| | Vmin) | | |

Table 1 is merely an example. In this embodiment, it is not limited to monitoring only four cycles. For example, if in the time period T2, 20 cycles of the current waveform of the charging current Ic are included, the 20 cycles can be also monitored in Table 1. Numerals in Table 1 are merely used as examples to explain the principle of an application, and are not intended to limit this embodiment of the present application or a measured result. Based on the foregoing content, if a calculated internal resistance value Rb already reaches a predetermined value, indicating that aging of the cell of the battery BAT already reaches a predetermined degree, the control signal Sc can be adjusted, to enable the charging current Ic to maintain a relatively low value, or is reduced from a high current value. The predetermined value may be, for example (but is not limited to), 80 mΩ, or may be set according to a battery model and a test result.

Table 2 is a table, in this embodiment, of a description of an operation of the control unit 110 setting a control signal Sc according to an obtained internal resistance value Rb calculated by the control unit 110.

TABLE 2

| | | |
|---|---|---|
| Status | When internal resistance | When internal resistance |
| | value Rb already reaches a | value Rb does not reach a |
| | predetermined value | predetermined value |
| Operation | Control unit 110 sets a | Control unit 110 sets a |
| that is | control signal Sc, to enable | control signal Sc, to |
| performed | the charging current Ic to | enable the charging |
| | have a first current value | current Ic to have a |
| | | second current value |

In Table 2, the first current value may be, for example, a standard charging current value or a charging current value lower than the standard charging current value, and the second current value may be, for example, a fast charging current value, where the first current value may be lower than the second current value.

According to an embodiment, in the time period T2, a change frequency of the waveform of the charging current Ic may not be excessively high. In other words, a cycle corresponding to the time period T3 may not be excessively short. If the cycle of the current waveform of the charging current Ic is excessively short, a change of the battery voltage Vb cannot easily reflect a status of embedding ions into the cell. This may cause reduction of precision of the internal resistance value Rb calculated by the control unit 110. If a battery of a common notebook computer is used as an example, the cycle of the current waveform corresponding to the time period T3 may be (but is not limited to) 10 seconds. An appropriate cycle of the current waveform may be adjusted and set according to a test result.

According to an embodiment, in FIG. 1, the control unit 110 may be a microcontroller unit (MCU), a processor, or an application-specific integrated circuit (ASIC). The measurement unit 130 may be an integrated circuit for measurement (gauge IC). The measurement signal Sb may be a current signal, a voltage signal, a binary code, or an ASCII code capable of being transmitted by using a flat cable (a bus). In FIG. 1, that the measurement unit 130 detects the battery voltage Vb of the battery BAT is used as an example. However, in another embodiment, the measurement unit 130 may alternatively measure a battery current output by the battery BAT. Because the battery current is directly proportional to the battery voltage Vb, the foregoing principle should still be applied.

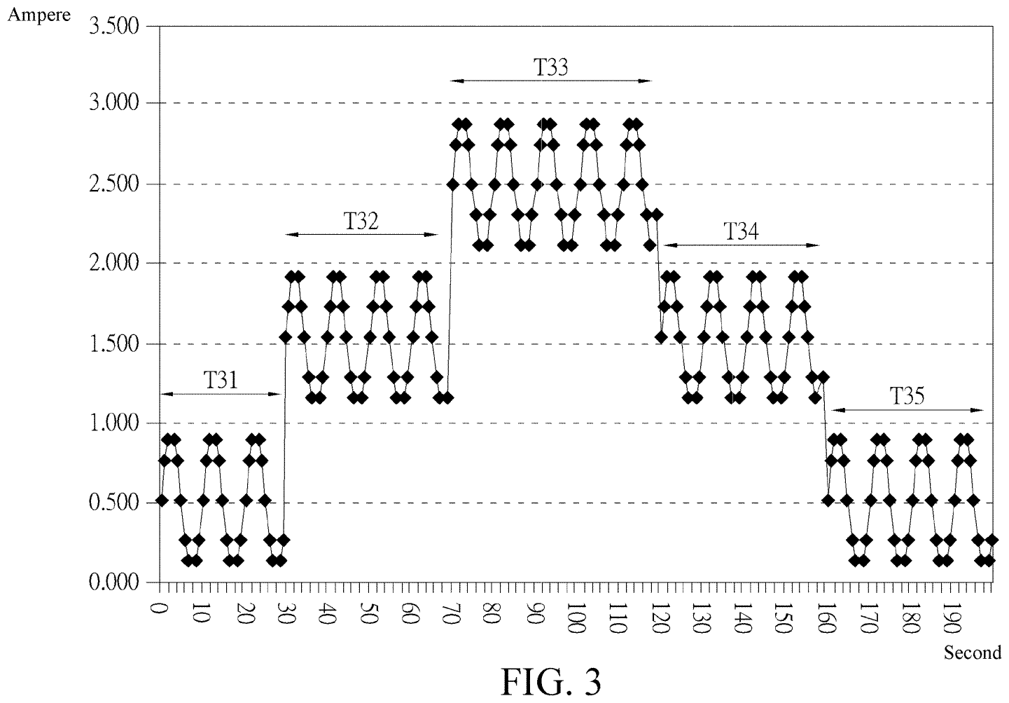

FIG. 3 is a schematic diagram of a waveform change of the charging current Ic in FIG. 1. In FIG. 1, the control unit 110 may update the control signal Sc, and the charging unit 120 may receive the control signal Sc, update the charging current Ic according to the control signal Sc, and output the updated charging current Ic to the battery BAT. According to this embodiment, an average current value of the updated charging current Ic may be updated. FIG. 3 shows an example in which a status of updating the average current value is described. In FIG. 3, in a time period T31, the control unit 110 may control an average current value of the charging current Ic to be approximately 0.5 amperes. The control unit 110 may use, in the time period T31, a charging current Ic having an oscillation waveform, to observe a change of the battery voltage Vb, and calculate an internal resistance value Rb of the battery BAT. If the internal resistance value Rb does not reach a predetermined value, indicating that an aging degree of the battery BAT can withstand a higher charging current, in a time period T32, the control unit 110 may increase the average current value of the charging current Ic to approximately 1.5 amperes. If in the time period T32, the control unit 110 obtains that an internal resistance value Rb of the battery BAT does not reach a predetermined value, the control unit 110 may control, in a time period T33, the average current value of the charging current Ic to be approximately 2.5 amperes.

If in a cycle in the time period T33, an internal resistance value Rb of the control unit 110 already reaches a predetermined value, indicating that in consideration of an aging degree of the battery BAT, the charging current Ic should be reduced, to slow down the aging. Therefore, in a time period T34, the average current value of the charging current Ic is adjusted to approximately 1.5 amperes. If in a subsequent cycle in the time period T34, an internal resistance value Rb of the control unit 110 already reaches a predetermined value, indicating that in consideration of an aging degree of the battery BAT, the charging current Ic should be further reduced. Therefore, in a time period T35, the average current value of the charging current Ic is controlled to be approximately 1.5 amperes.

In FIG. 3, in the time periods T31 to T35, the internal resistance value Rb of the battery BAT can be dynamically detected, to apply a relatively high charging current Ic when the internal resistance value Rb of the battery does not exceed a predetermined value, so as to simultaneously reach a high charging speed and slow battery aging. In FIG. 3, for a setting of a step form of the charging current Ic, there are totally three steps: 0.5 ampere, 1.5 amperes, and 2.5 amperes. Numerals and waveforms in FIG. 3 are merely examples. According to this embodiment, more steps can be designed provided that they are allowed by a battery specification and a control system, to achieve relatively precise control.

In addition, in FIG. 3, in each time period, the charging current Ic continuously oscillates, and therefore, the control unit 110 may continuously detect the internal resistance value Rb. However, in another embodiment, after the internal resistance value Rb is obtained, and that the internal resistance value Rb is not excessively high is determined, the charging current Ic may be further adjusted to be a fixed value (for example, a maximum value in the time period), so that a highest charging speed is reached. Next, in a time period in which the battery BAT is to be checked, the charging current Ic is adjusted to have an oscillation waveform, to enable the control unit 110 to detect the internal resistance value Rb. The time period in which the battery BAT is to be checked may be, for example, a specific time period every day or every week. Alternatively, for example, calculation of the internal resistance value Rb is performed every n minutes (n is a positive integer). This can be set in the control unit 110.

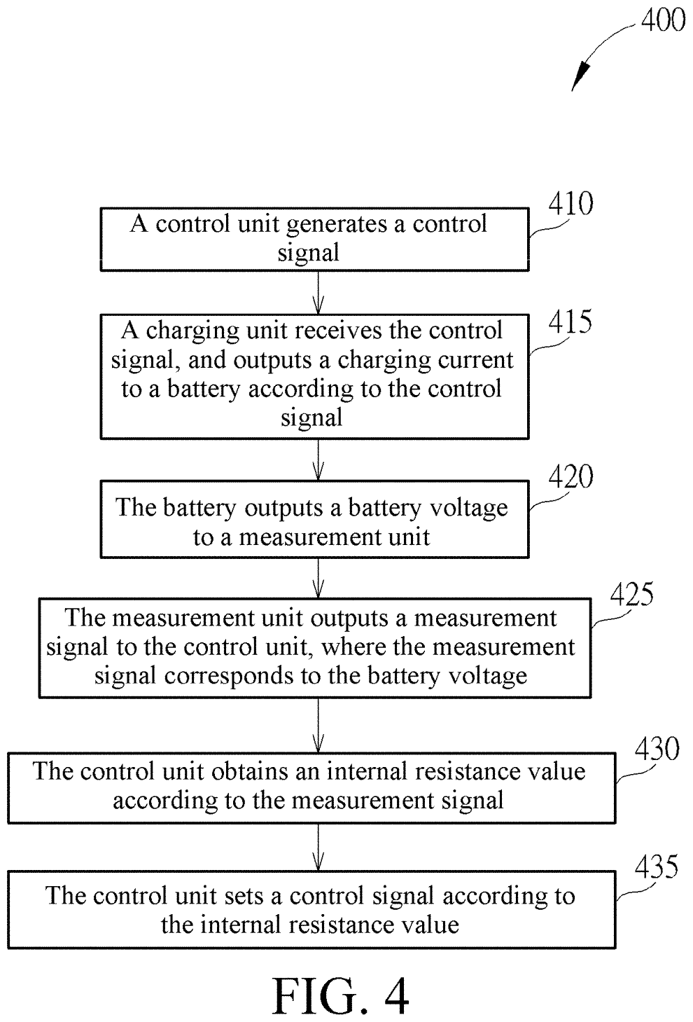

FIG. 4 is a flowchart of a battery charging method 400 for the battery charging system 100 in FIG. 1. The battery charging method 400 may include the following steps:

Step 410: A control unit 110 generates a control signal Sc.

Step 415: A charging unit 120 receives the control signal Sc and outputs a charging current Ic to a battery BAT according to the control signal Sc.

Step 420: The battery BAT outputs a battery voltage Vb to a measurement unit 130.

Step 425: The measurement unit 130 outputs a measurement signal Sb to the control unit 110, where the measurement signal Sb corresponds to the battery voltage Vb.

Step 430: The control unit 110 obtains an internal resistance value Rb of the battery according to the measurement signal Sb.

Step 435: The control unit 110 sets a control signal Sc according to the internal resistance value Rb.

In the step 430, a process of calculating the internal resistance value Rb is described above, and therefore, is not described again. In the step 435, the internal resistance value Rb does not reach a predetermined value, the control signal Sc may be set to increase the charging current Ic, or not to reduce the charging current Ic (if the charging current Ic is originally a high current). If the internal resistance value Rb already reaches a predetermined value, the control signal Sc can be set to reduce the charging current Ic, or not to increase the charging current Ic (if the charging current Ic is originally a low current). According to this embodiment, the steps 410 to 435 may be cyclically performed, and after the step 435 is performed, the method may be performed again starting from the step 410 according to a requirement.

It can be learned based on the above that by using the battery charging system and method provided in the embodiments, an appropriate charging current may be input dynamically and in real time according to an internal resistance value and an aging status of a battery, in each period during use of the battery. Therefore, fast charging and avoidance of shortening of a service life of the battery can be balanced, to help alleviate an engineering problem in the art.

The foregoing descriptions are merely preferred embodiments in the present application, and equivalent changes and modifications made according to the claims of the present application should all fall within the scope of the present application.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A battery charging system, comprises:
a control unit, configured to generate and output a control signal;
a charging unit, coupled to the control unit and a battery, wherein the charging unit is configured to receive the control signal, generate a charging current according to the control signal, and output the charging current to charge the battery; and
a measurement unit, coupled to the battery and the control unit, and configured to measure a battery voltage output by the battery, and output a measurement signal to the control unit, wherein the measurement signal corresponds to the battery voltage.

2. The battery charging system according to claim 1, wherein the control unit is further configured to obtain an internal resistance value of the battery according to the measurement signal, and set the control signal according to the internal resistance value.

3. The system according to claim 2, wherein the control unit sets the control signal according to the internal resistance value, so that the charging current has a fast charging current value or a standard charging current value, wherein the fast charging current value is greater than the standard charging current value.

4. The battery charging system according to claim 1, wherein
the charging current forms a current waveform on a time axis according to the control signal, and the battery voltage forms a voltage waveform on the time axis; and
the control unit is further configured to obtain an internal resistance value of the battery according to the current waveform and the voltage waveform, and set the control signal according to the internal resistance value.

5. The battery charging system according to claim 4, wherein the current waveform is a waveform that comprises a sinusoidal wave, a triangular wave, a rectangular wave, or a repeated particular waveform.

6. The battery charging system according to claim 4, wherein the control unit sets the control signal according to the internal resistance value, so that the charging current has a fast charging current value or a standard charging current value, wherein the fast charging current value is greater than the standard charging current value.

7. The battery charging system according to claim 1, wherein
the charging current forms a current waveform on a time axis according to the control signal, and in a predetermined cycle of the current waveform, the charging current has a maximum current value and a minimum current value, and the battery voltage has a maximum voltage value and a minimum voltage value; and
the control unit is further configured to obtain an internal resistance value of the battery according to the maximum voltage value, the minimum voltage value, the maximum current value, and the minimum current value, and set the control signal according to the internal resistance value.

8. The battery charging system according to claim 7, wherein the current waveform is a waveform that comprises a sinusoidal wave, a triangular wave, a rectangular wave, or a repeated particular waveform.

9. The battery charging system according to claim 7, wherein the control unit sets the control signal according to the internal resistance value, so that the charging current has a fast charging current value or a standard charging current value, wherein the fast charging current value is greater than the standard charging current value.

10. The battery charging system according to claim 1, wherein
the charging current forms a current waveform on a time axis according to the control signal, and in a predetermined cycle of the current waveform, the charging current has a maximum current value and a minimum current value, and the battery voltage has a maximum voltage value and a minimum voltage value; and
the control unit is further configured to obtain an internal resistance value of the battery according to the maximum voltage value, the minimum voltage value, the maximum current value, and the minimum current value, and set the control signal according to the internal resistance value, wherein
the internal resistance value is directly proportional to a quotient of a difference between the maximum voltage value and the minimum voltage value and a difference between the maximum current value and the minimum current value.

11. The battery charging system according to claim 10, wherein the current waveform is a waveform that comprises a sinusoidal wave, a triangular wave, a rectangular wave, or a repeated particular waveform.

12. The battery charging system according to claim 10, wherein the control unit sets the control signal according to the internal resistance value, so that the charging current has a fast charging current value or a standard charging current value, wherein the fast charging current value is greater than the standard charging current value.

13. The battery charging system according to claim 1, wherein
the control unit is a microcontroller, a processor, or an application-specific integrated circuit; and
the measurement signal is a current signal, a voltage signal, a binary code, or an ASCII code.

14. A battery charging method, applied to a battery charging system, wherein the battery charging system comprises a control unit, a charging unit, and a measurement unit, and the method comprises:
generating, by the control unit, a control signal;
receiving, by the charging unit, the control signal, and outputting a charging current to a battery according to the control signal;
outputting, by the battery, a battery voltage to the measurement unit; and
outputting, by the measurement unit, a measurement signal to the control unit, wherein the measurement signal corresponds to the battery voltage.

15. The battery charging method according to claim 14, further comprising:
obtaining, by the control unit, an internal resistance value of the battery according to the measurement signal; and
setting, by the control unit, the control signal according to the internal resistance value.

16. The battery charging method according to claim 15, wherein
the charging current forms a current waveform on a time axis according to the control signal, and the battery voltage forms a voltage waveform on the time axis; and
the obtaining, by the control unit, the internal resistance value of the battery according to the measurement signal comprises:
obtaining, by the control unit, the internal resistance value according to the current waveform and the voltage waveform.

17. The battery charging method according to claim 15, wherein
the charging current forms a current waveform on a time axis according to the control signal, and in a predetermined cycle of the current waveform, the charging current has a maximum current value and a minimum current value, and the battery voltage has a maximum voltage value and a minimum voltage value; and
the obtaining, by the control unit, the internal resistance value of the battery according to the measurement signal comprises:
obtaining, by the control unit, the internal resistance value according to the maximum voltage value, the minimum voltage value, the maximum current value, and the minimum current value.

18. The battery charging method according to claim 17, wherein
the obtaining, by the control unit, the internal resistance value according to the maximum voltage value, the minimum voltage value, the maximum current value, and the minimum current value comprises:
obtaining, by the control unit, the internal resistance value according to a quotient of a difference between the maximum voltage value and the minimum voltage value and a difference between the maximum current value and the minimum current value.

19. The battery charging method according to claim 14, further comprising:
updating, by the control unit, the control signal;
receiving, by the charging unit, the control signal, updating the charging current according to the control signal, and outputting the updated charging current to the battery, wherein
an average current value of the updated charging current is updated.
